(19) United States
(12) Patent Application Publication
(10) Pub. No.: US 2012/0149213 A1
(43) Pub. Date: Jun. 14, 2012

(54) BOTTOM UP FILL IN HIGH ASPECT RATIO TRENCHES

(76) Inventors: Lakshminarayana Nittala, Sunnyvale, CA (US); Karena Shannon, San Jose, CA (US); Nerissa Draeger, Fremont, CA (US); Megha Rathod, San Jose, CA (US); Harald Te Nijenhuis, San Jose, CA (US); Bart Van Schravendijk, Sunnyvale, CA (US); Michael Danek, Cupertino, CA (US)

(21) Appl. No.: 13/313,735

(22) Filed: Dec. 7, 2011

Related U.S. Application Data
(60) Provisional application No. 61/421,562, filed on Dec. 9, 2010.

(51) Int. Cl. H01L 21/31; C23C 16/02; C23C 16/40

(52) U.S. Cl. 438/783; 438/778; 118/696; 257/E21.24

(57) ABSTRACT

Provided are novel methods of filling gaps with a flowable dielectric material. According to various embodiments, the methods involve performing a surface treatment on the gap to enhance subsequent bottom up fill of the gap. In certain embodiments, the treatment involves exposing the surface to activated species, such as activated species of one or more of nitrogen, oxygen, and hydrogen. In certain embodiments, the treatment involves exposing the surface to a plasma generated from a mixture of nitrogen and oxygen. The treatment may enable uniform nucleation of the flowable dielectric film, reduce nucleation delay, increase deposition rate and enhance feature-to-feature fill height uniformity.

### CROSS-REFERENCE TO RELATED APPLICATION

This application claims priority under 35 U.S.C. §119(e) to U.S. Provisional Application 61/421,562 entitled “BOTTOM UP FILL IN HIGH ASPECT RATIO TRENCHES,” filed Dec. 9,2010, all of which is incorporated in its entirety by this reference.

### BACKGROUND OF THE INVENTION

It is often necessary in semiconductor processing to fill high aspect ratio gaps with insulating material. This is the case for shallow trench isolation (STI), inter-metal dielectric (IMD) layers, inter-layer dielectric (ILD) layers, pre-metal dielectric (PMD) layers, passivation layers, etc. As device geometries shrink and thermal budgets are reduced, void-free filling of narrow width, high aspect ratio (AR) features (e.g., AR>6:1) becomes increasingly difficult due to limitations of existing deposition processes.

### SUMMARY OF THE INVENTION

Provided are novel methods of filling gaps with a flowable dielectric material. According to various embodiments, the methods involve performing a surface treatment on the gap to enhance subsequent bottom up fill of the gap. In certain embodiments, the treatment involves exposing the surface to activated species, such as activated species of one or more of nitrogen, oxygen, and hydrogen. In certain embodiments, the treatment involves exposing the surface to a plasma generated from a mixture of nitrogen and oxygen. The treatment may enable uniform nucleation of the flowable dielectric film, reduce nucleation delay, increase deposition rate and enhance feature-to-feature fill height uniformity. Also provided are apparatuses for implementing the methods described herein.

One aspect of the subject matter described herein includes a method of treating of filling a gap with a flowable material. The method can include providing a substrate including a gap to be filled to a treatment chamber, the gap including a bottom surface and one or more sidewall surfaces; exposing a surface of the gap to reactive hydrogen, nitrogen or oxygen species; and after exposing the surface of the gap to reactive species, depositing a flowable dielectric film in the gap.

In some embodiments, depositing a flowable dielectric film in the gap can include introducing a silicon-containing precursor and an oxidant in a chamber containing the substrate under conditions such that the flowable dielectric film is formed. The method can further include densifying at least a portion of the deposited film. According to various embodiments, the surface can be a solid silicon-containing material or a metal. In some embodiments, the gap surface is exposed to nitrogen and oxygen species prior to the deposition of any flowable dielectric film in the gap.

One or more surfaces can be exposed to the reactive hydrogen, nitrogen or oxygen species. In some embodiments, the bottom and one or more sidewall surfaces are exposed to the reactive species. In some embodiments, the method can include generating a plasma from a gas including one or more of a hydrogen-containing, a nitrogen-containing compound and an oxygen-containing compound. The surface can be exposed to the plasma. According to various embodiments, the plasma can be generated in the treatment chamber or remote to the chamber. The hydrogen, nitrogen and oxygen species can include ions and/or radicals in some embodiments.

In some embodiments, the method can include exposing a gas including one or more of a hydrogen-containing compound, a nitrogen-containing compound and an oxygen-containing compound to ultraviolet light or other energy source. This can be performed in addition to generating a plasma or without generating a plasma.

In some embodiments, exposing the gap to nitrogen and oxygen species includes introducing nitrogen and oxygen to the treatment chamber in a ratio of between about 1:2 to 1:30, between about 1:5 to 1:30, or between about 1:10 to 1:20.

According to various embodiments, the flowable dielectric material can be deposited in the treatment chamber, or the substrate can be transferred to a separate deposition chamber. According to various embodiments, nitrogen species can be generated from one more of the following gases: N₂, NH₃, N₂H₄, N₂O, NO and NO₂. Oxygen species can be generated from one or more of the following gases: O₂, O₃, H₂O, H₂O₂, NO, NO₂ and CO₂. Hydrogen species can be generated from one or more of the following gases: H2, H₂O, H₂O₂, and NH₃.

In some embodiments, prior to depositing a flowable film in the gap, a silicon-containing precursor can be flowed into the chamber. In certain embodiments, prior to depositing a flowable film in the gap, a silicon-containing precursor can be flowed into the chamber.

Another aspect of the invention relates to a method of treating a substrate including a gap in a treatment chamber, the gap including a bottom surface and one or more sidewall surfaces. The method can include exposing a surface of the gap to activated species generated from a gas including at least one of an oxygen-containing gas, a hydrogen-containing gas, and a nitrogen-containing gas. After exposing the surface of the gap to the activated species, a flowable dielectric film in the gap can be deposited in the gap.

Examples of gas compositions include hydrogen and substantially no oxygen- or nitrogen-containing compounds, an oxygen-containing compound and substantially no nitrogen-containing compounds, and a nitrogen-containing compound and substantially no oxygen-containing compounds.

Yet another aspect relates to a method including providing a substrate including a gap to a treatment chamber, introducing oxygen and nitrogen species to the treatment chamber containing the substrate; and after introducing oxygen and nitrogen species to the treatment chamber, partially or wholly filling the gap with a flowable dielectric material.

In some embodiments, introducing the oxygen and nitrogen species to the treatment chamber can include introducing a process gas including an oxygen-containing compound and a nitrogen-containing compound to the treatment chamber and generating a plasma from the process gas.

In some embodiments, introducing the oxygen and nitrogen species to the treatment chamber can include generating a plasma from a process gas including one or more of an oxygen-containing compound, hydrogen-containing compound and a nitrogen-containing compound and introducing species from the generated plasma to the treatment chamber. For example, a gas composition may be one of H₂, H₂/N₂, H₂/O₂, O₂, O₃, N₂, NH₃ and N₂/O₂, each of which may optionally include one or more inert gases such as He or Ar.

Yet another aspect relates to a method including providing a substrate including a gap to be filled to a treatment chamber, the gap including a bottom surface and one or more sidewall surfaces; exposing a gas including at least one of an oxygen-containing gas, a hydrogen-containing gas, and a nitrogen-containing gas to ultraviolet light to generate activated species; exposing a surface of the gap to the activated species; and after exposing the surface of the gap to the activated species, depositing a flowable dielectric film in the gap.

Yet another aspect relates to an apparatus including a treatment chamber configured to contain a partially manufactured semiconductor substrate and a deposition chamber configured to contain a partially manufactured semiconductor substrate; and a controller including program instructions for introducing activated species to the treatment chamber while it contains the substratem, transferring the substrate under vacuum to the deposition chamber; and introducing a silicon-containing precursor and an oxidant to the deposition chamber to thereby deposit a flowable oxide film on the substrate.

Further details of these aspects as well as other innovative aspects of the subject described in this disclosure are given below.

### BRIEF DESCRIPTION OF DRAWINGS

FIGS. 1-3 are process flow diagram illustrating operations in dielectric deposition methods according to various embodiments.

FIGS. 4A-4C are schematic illustrations showing examples of gaps that are filled according to various embodiments.

FIG. 5 shows images of gaps after two deposition cycles, one image of gaps filled with flowable oxide following an O₂/N₂ pre-treatment prior to the first deposition cycle and one image of gaps filled with flowable oxide without a pre-treatment prior to the first deposition cycle.

FIG. 6 shows images of gaps after two deposition cycles comparing various pre-treatment operations.

FIG. 7 is a plot of fill height as a function of N₂ flow rates for a O₂/N₂ pre-fill treatment.

FIG. 8 is a plot of fill non-uniformity as a function of N₂ flow rates for a O₂/N₂ pre-fill treatment.

FIG. 9 shows images of gaps after two depositions cycles comparing various pre-treatment operations.

FIGS. 10A and 10B are top view diagrams illustrating multi-station apparatuses suitable for practicing various embodiments.

FIG. 11 is a schematic diagram illustrating a deposition and/or treatment chamber suitable for practicing various embodiments.

FIG. 12 is simplified illustration of a cure module suitable for practicing various embodiments.

FIG. 13 is simplified illustration of a HDP-CVD module suitable for practicing various embodiments.

### DETAILED DESCRIPTION OF THE INVENTION

INTRODUCTION

The present invention pertains to methods of filling gaps on a substrate. In certain embodiments, the methods pertain to filling high aspect (AR) ratio (typically at least 6:1, for example 7:1 or higher), narrow width (e.g., sub-50 nm) gaps. In certain embodiments, the methods pertain filling both low AR gaps (e.g., wide trenches). Also in certain embodiments, gaps of varying AR may be on the substrate, with the embodiments directed at filling low and high AR gaps.

It is often necessary in semiconductor processing to fill high aspect ratio gaps with insulating material. This is the case for shallow trench isolation (STI), inter-metal dielectric (IMD) layers, inter-layer dielectric (ILD) layers, pre-metal dielectric (PMD) layers, passivation layers, etc. As device geometries shrink and thermal budgets are reduced, void-free filling of narrow width, high aspect ratio (AR) features (e.g., AR>6:1) becomes increasingly difficult due to limitations of existing deposition processes. In a particular example, a PMD layer is provided between the device level and the first layer of metal in the interconnect level of a partially fabricated integrated circuit. The methods described herein include dielectric deposition in which gaps, (e.g., the gaps between gate conductor stacks) are filled with dielectric material. In another example, the methods are used for shallow trench isolation processes in which trenches are formed in semiconductor substrates to isolate devices. The methods described herein include dielectric deposition in these trenches. The methods can also be used for back end of line (BEOL) applications, in addition to front end of line (FEOL) applications. These can include filling gaps at an interconnect level.

The disclosed methods may be implemented in a process with lithography and/or patterning processes preceding or following the disclosed methods. Further, the disclosed apparatuses may also be implemented in systems including lithography and/or patterning hardware for semiconductor fabrication.

As used herein, the term “flowable dielectric film” is a flowable doped or undoped dielectric film having flow characteristics that provide void-free fill of a gap. According to various embodiments, the film may flow into the gap and/or may form in the gap. As used herein, the term “flowable oxide film” is a flowable doped or undoped silicon oxide film having flow characteristics that provide void-free fill of a gap. The flowable oxide film may also be described as a soft jelly-like film, a gel having liquid flow characteristics, a liquid film, or a flowable film. In certain embodiments, forming a flowable film involves reacting a silicon-containing precursor and an oxidant to form a condensed flowable film on the substrate. The flowable oxide deposition methods described herein are not limited to a particular reaction mechanism, e.g., the reaction mechanism may involve an adsorption reaction, a hydrolysis reaction, a condensation reaction, a polymerization reaction, a vapor-phase reaction producing a vapor-phase product that condenses, condensation of one or more of the reactants prior to reaction, or a combination of these. The substrate is exposed to the process gases for a period sufficient to deposit a flowable film to fill at least some of the gap. The deposition process typically forms soft jelly-like film with good flow characteristics, providing consistent fill. In certain embodiments, the flowable film is an organo-silicon film, e.g., an amorphous organo-silicon film. In other embodiments, the flowable oxide film may have substantially no organic material.

According to various embodiments, the processes may also involve deposition of solid oxide films, e.g., HDP oxide films and TEOS oxide films, e.g., as planar dielectric layers. As deposited HDP oxide films and TEOS oxide films are dense, solid and not flowable, whereas as-deposited flowable oxide films are not fully densified and less dense and softer than HDP oxide and TEOS oxide films. The term “flowable oxide film” may be used herein to refer to flowable oxide films that have undergone a densification or cure process that wholly or partially densifies the films as well as-deposited flowable oxide films. Details of flowable oxide deposition processes are described further below.

One aspect of the invention relates to treatment of a substrate surface prior to flowable dielectric deposition. The description below provides examples of process sequences in which the treatment methods may be employed. The methods may also be employed in accordance with the flowable deposition processes described in the following: U.S. Pat. Nos. 7,074,690; 7,524,735; 7,582,555; and 7,629,227; and U.S. patent application Ser. Nos. 11/834,581, 12/334,726, 12/566,085, and 61/285,091, all of which are incorporated by reference herein.

### Process Overview

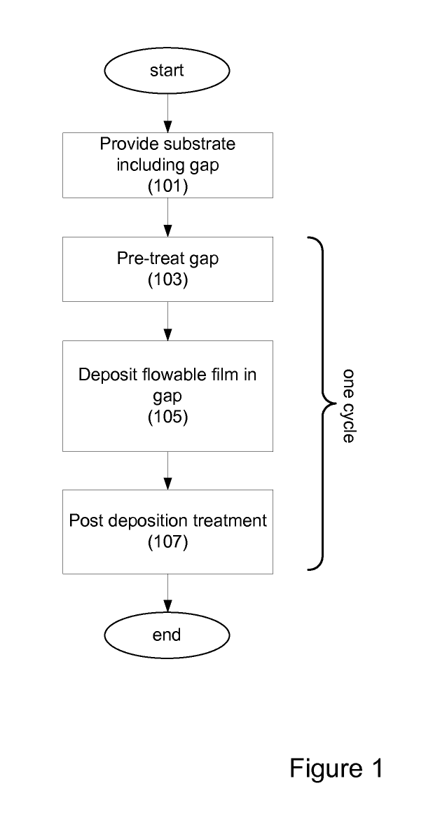

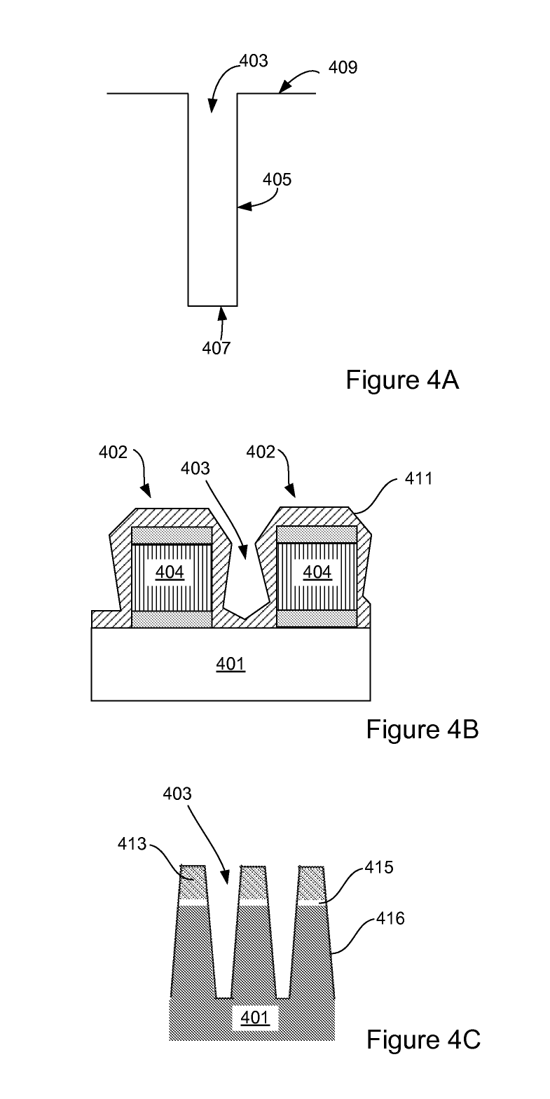

As indicated above, one aspect of the invention relates to treatment of substrate surfaces prior to flowable dielectric deposition. FIG. 1 is a process flow diagram illustrating one example of a process involving a pre-treatment operation. First, a substrate having a gap is provided. (Block 101). In many cases, the substrate includes multiple gaps, which may be trenches, holes, vias, etc. FIG. 4A is an illustration of a cross-sectional view of a gap 403. The gap 403 is defined by sidewalls 405 and bottom 407. It may be formed by various techniques, depending on the particular integration process, including patterning and etching blanket (planar) layers on a substrate or by building structures having gaps there-between on a substrate. In certain embodiments a top of the gap 403 is defined as the level of planar surface 409. Specific examples of gaps are provided in FIGS. 4B and 4C. In FIG. 4B, a gap 403 is shown between two gate structures 402 on a substrate 401. Substrate 401 may be a semiconducting substrate such as silicon, silicon-on-insulator (SOI), gallium arsenide and the like, and may contain n-doped and p-doped regions (not shown). Gate structures 402 include gates 404 and silicon nitride of silicon oxy-nitride layer 411. In certain embodiments, the gap is re-entrant, i.e., the sidewalls taper inwardly as they extend up from the bottom of the gap; gap 403 in FIG. 4B is an example.

FIG. 4C shows another example of gap to be filled. In this example, gap 403 is a trench formed in silicon substrate 401. The sidewalls and bottom of the gap are defined by liner layer 416, e.g., a silicon nitride or silicon oxynitride layer, pad silicon oxide layer 415 and pad silicon nitride layer 413. FIG. 4C is an example of a gap that may be filled during a STI process. In certain cases, liner layer 416 is not present. In certain embodiments, the sidewalls of silicon substrate 401 are oxidized.

FIGS. 4B and 4C provide examples of gaps that may be filled with dielectric material in a semiconductor fabrication process. The methods described herein may be used to fill any gap that requires dielectric fill. In certain embodiments, the gap critical dimension is the order of about 1-50 nm, in some cases between about 2-30 nm or 4-20 nm, e.g. 13 nm. Critical dimension refers to the width of the gap opening at its narrowest point. In certain embodiments, the aspect ratio of the gap is between 3:1 and 60:1. According to various embodiments, the critical dimension of the gap is 32 nm or below and/or the aspect ratio is at least about 6:1.

As indicated above, a gap typically is defined by a bottom surface and sidewalls. The term sidewall or sidewalls may be used interchangeably to refer to the sidewall or sidewalls of a gap of any shape, including a round hole, a long narrow trench, etc. The sidewall and bottom surfaces that define the gap may be one or multiple materials. Examples of gap sidewall and/or bottom materials include nitrides, oxides, carbides, oxynitrides, oxycarbides, silicides, as well as bare silicon or other semiconductor material. Particular examples include SiN, SiO₂, SiC, SiON, NiSi, polysilicon and any other silicon-containing material. Further examples of gap sidewall and/or bottom materials used in BEOL processing include copper, tantalum, tantalum nitride, titanium, titanium nitride, ruthenium and cobalt.

In certain embodiments, prior to flowable dielectric deposition, the gap is provided with a liner, barrier or other type of conformal layer formed in the gap, such that all or a portion of the bottom and/or sidewalls of the gap is the conformal layer.

Returning to FIG. 1, the gap is pre-treated (Block 103). Pre-treatment operations are described further below; in certain embodiments, they involve exposing one or more surfaces of the gap to an O₂/N₂ plasma. In certain embodiments, block 103 can involve exposing one or more surfaces of the gap to a H₂ plasma. As discussed further below, certain pre-treatment operations described herein decrease nucleation delay and improve bottom up fill. The treatment may also improve nucleation uniformity or interface adhesion between the flowable oxide and substrate material. In many embodiments, all surfaces of the gap are exposed to the treatment species. In certain embodiments, a bottom surface is preferentially exposed, e.g., by an anisotropic plasma treatment process. Such a process may involve biasing the substrate. In other embodiments, a substrate bias is avoided to prevent unwanted damage to the gap surfaces.

A flowable dielectric film is then deposited in the gap (Block 105). In many embodiments, this involves exposing the substrate to gaseous reactants including a dielectric precursor and an oxidant such that a condensed flowable film forms in the gap. According to various embodiments, various reaction mechanisms may take place including on or more of the reaction(s) occurring in the gap and reaction(s) occurring of on field regions with at least some of film flowing into the gap. Examples of deposition chemistries and reaction mechanisms according to various embodiments are described below; however, the methods are not limited to a particular chemistry or mechanism. In many embodiments, the dielectric precursor is a silicon-containing compound and the oxidant a compound such as a peroxide, ozone, oxygen, steam, etc. As described further below, the deposition chemistry may include on or more of a solvent and a catalyst as well.

The process gases may be introduced into the reactor simultaneously, or one or more component gases may be introduced prior to the others. U.S. patent application Ser. No. 12/566,085, incorporated by reference above, provides a description of reactant gas sequences that may be used in accordance with certain embodiments. The reaction may be a non-plasma (chemical) reaction or be a plasma-assisted reaction. U.S. patent application Ser. No. 12/334,726, incorporated by reference above, describes depositing flowable dielectric films by plasma-enhanced chemical vapor deposition (PECVD) processes.

According to various embodiments, the deposition operation may proceed until the gap is only partially filled, or at least until the gap is wholly filled, with flowable dielectric material. In certain embodiments, a gap is filled via a single cycle, with a cycle including a pre-treatment operation and a deposition operation, and if performed, a post-deposition treatment operation. In other embodiments, a multi-cycle reaction is performed, and operation 105 only partially fills the gap.

After the deposition operation, a post-deposition treatment operation is performed (Block 107). The post-deposition treatment operation may include one or more operations to densify the as-deposited film and/or chemically convert the as-deposited film to the desired dielectric material. For example, the post-deposition treatment may involve an oxidizing plasma that converts the film to an Si—O network and densifies the film. In other embodiments, different operations may be performed for conversion and densification. Densification treatments may also be referred to as cures or anneals. The post-deposition treatment may be perform in situ, i.e., in the deposition module, or ex-situ in another module, or in a combination of both. Further description of post-deposition treatment operations is provided below. According to various embodiments, a post-treatment operation may affect all of, or only a top portion of the deposited film. For example, in certain embodiments, exposure to an oxidizing plasma oxidizes the entire depth of the deposited film but densifies only a top portion. In other embodiments, the entire thickness deposited in the preceding operation is densified.

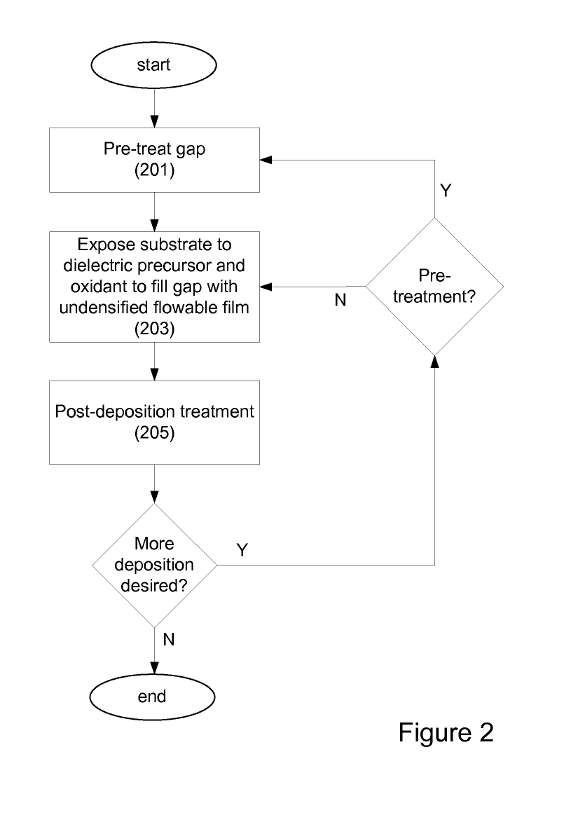

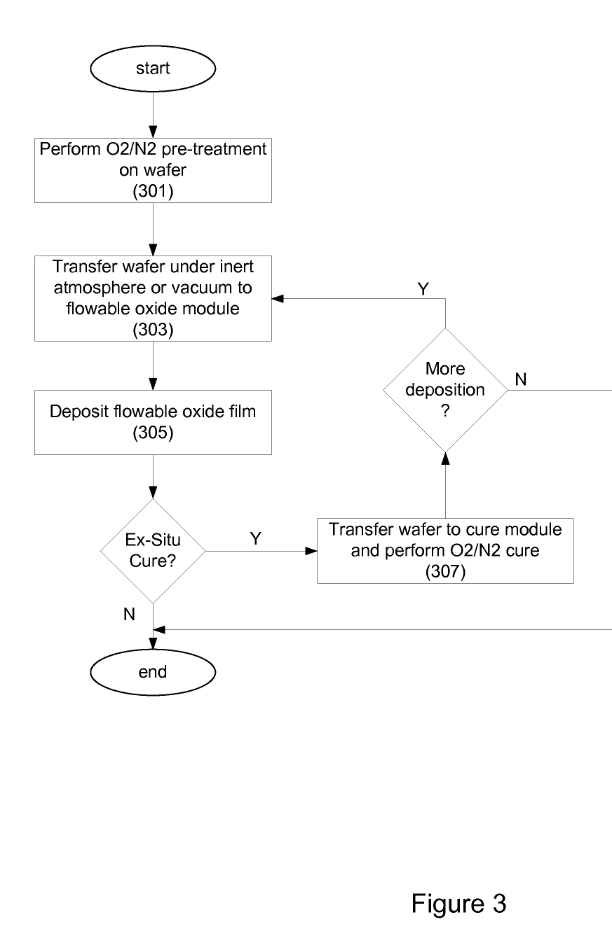

FIG. 2 is a process flow diagram illustrating a multi-cycle deposition operation according to certain embodiments. First, a gap is pre-treated as described above (Block 201). After pre-treatment, the gap is exposed to a dielectric precursor and oxidant to deposit a flowable film in the gap (Block 203). A post-deposition treatment is then performed, e.g., to densify all or a portion of the deposited film (Block 205). At this point, if no more deposition is desired, e.g., if the gap is filled, the process ends and the wafer may be ready for further processing. If more deposition is desired, the process returns to operation 201 or 203, depending on whether a pre-deposition treatment is desired. In many embodiments, the decision to perform a pre-treatment operation is based on the post-deposition treatment operation. For example, in certain embodiments, the post-deposition operation may create a top densified portion or crust on which nucleation is difficult. A pre-treatment operation may be employed to improve nucleation and bottom-up fill in the subsequent deposition. In other embodiments, the post-deposition operation may not be necessary. In still other embodiments, a single operation may function as both a post-deposition operation and a pre-treatment operation of the subsequent deposition. An example of such a process is described below with reference to FIG. 3.

Regardless of whether process returns to operation 201 or 203, the gap at this point is partially filled and includes at least a bottom surface of an oxide (or other dielectric) from a previous flowable film deposition cycle. In certain embodiments, a small amount of oxide is also present on the sidewalls from the previous deposition cycles. This amount may be less than a few Angstroms in certain embodiments. The process is then repeated until the desired thickness is deposited. Multi-cycle deposition processes may be used to reduce or eliminate a density gradient in a filled feature. Examples of such processes are described in U.S. patent application Ser. No. 11/834,581, incorporated by reference above.

FIG. 3 is a flow diagram illustrating an example of a multi-cycle process that uses an O₂/N₂ treatment. Other pre- and/or post-deposition treatments may be used instead of this treatment in other embodiments. The process begins with treating the wafer with an O₂/N₂ plasma. (Block 301). The wafer is then transferred to a flowable oxide deposition module under inert atmosphere or vacuum (Block 303). Examples of inert atmospheres include He, Ar and N₂. In other embodiments, the pre-treatment is performed in situ in the deposition module and the transfer operation is not required. Once in the deposition module, a flowable oxide film is deposited to partially fill one or more gaps on the substrate. (Block 305). If the desired thickness is deposited and no cure is desired, the process ends. If an ex-situ cure is to be performed the wafer is transferred to a cure module and exposed to an O₂/N₂ plasma (Block 307). The cure module may be the same or a different module as used in operation 301. Further, the process conditions (e.g., relative flow rates, power, etc.) may be the same or different than in operation 301. If more deposition is desired, the process returns to operation 303, with the wafer transferred to the deposition module. In this embodiment, the post-deposition O₂/N₂ densifies the deposited film and prepares the surface for another deposition, removing the need for a separate pre-treatment operation. The process continues until the desired thickness is obtained. While a NO₂/N₂ treatment is depicted in block 301 and a O₂/N₂ cure is depicted in block 307 of FIG. 3, other chemistries may be used in one or both of these blocks instead of O₂/N₂. These include O₂, O₃, N₂, O₂/H₂, N₂O, NH₃ and H₂, each of which may optionally include an inert gas.

FIGS. 1-3 above provide examples of process flow in accordance with various embodiments. One of ordinary skill in the art will understand that the flowable dielectric deposition methods described herein may be used with other process flows, and that specific sequences as well as the presence or absence of various operations will vary according to implementation.

### Pre-Treatment

According to various embodiments, pre-treatment operations that improve nucleation and/or bottom up fill are provided. As described above, the pre-treatment operation may take place prior to any flowable dielectric deposition. In multi-cycle operations, the pre-treatment may or may not be performed prior to subsequent deposition operations.

According to various embodiments, pre-treatment operations described herein involve exposing at least a portion of the surface on which the film is to be deposited to one or more of a hydrogen-containing, a nitrogen-containing and an oxygen-containing compound, e.g., N₂ and O₂, or to species derived from these compounds. Examples of nitrogen-containing compounds include N₂, NH₃, N₂H₄, N₂O, NO and NO₂. Examples of oxygen-containing compounds include O₂, O₃, H₂O, H₂O₂, NO, NO₂ and CO₂. Examples of hydrogen-containing compounds include H₂, H₂O, H₂O₂, and NH₃. In certain embodiments, a pre-treatment operation described herein involves exposing at least a portion of the surface on which the film is to be deposited to a nitrogen-containing compound with no oxygen-containing compounds (or species derived from these compounds). In certain embodiments, a pre-treatment operation described herein involves exposing at least a portion of the surface on which the film is to be deposited to an oxygen-containing compound with no nitrogen-containing compounds (or species derived from these compounds).

In certain embodiments, the treatment involves exposing the surface to a plasma generated from gases that contain nitrogen and oxygen. An inert gas such as helium, argon, krypton or xenon, may be present in the gas mixture used to generate the plasma. In certain embodiments, hydrogen (H₂) may be present alone or in combination with other inert and reactive species. In other embodiments, the gas mixture used to generate the plasma may consist essentially of a nitrogen-containing gas, an oxygen-containing gas, and optionally an inert gas, e.g., N₂/O₂, N₂/O₂/Ar, NO₂/Ar, etc. Still further, in certain embodiments, the gas mixture used to generate the plasma may consist essentially an optional inert gas and compounds including only nitrogen and/or oxygen. Still further, in certain embodiments, the gas used to generate the plasma may consist essentially an optional inert gas and hydrogen gas. One skilled in the art will recognize that the actual species present in the plasma may be a mixture of different species derived from these gases. Activated species present in the plasma may include ions, radicals and high energy atoms and molecules. In certain embodiments, no ions or electrons are present in significant amounts. In the same or other embodiments, the gases are introduced to the treatment chamber or module in the presence of one or more energies generated from a thermal energy source, a light source (including ultraviolet and/or infrared light sources), and microwave sources. The gases may be exposed to the one or more energies prior to and/or during treatment of the surface. In certain embodiments, activated species are formed from the exposure.

In embodiments in which the treatment involves generating a plasma, a remote plasma generator such as an Astron® remote plasma source, or an inductively or capacitively coupled plasma generator may be used. According to various embodiments, the treatment module may be the same or a different module than the deposition module. Examples of modules configured to expose a substrate to a treatment plasma are provided below. Plasma power is high enough to make the pre-treat effective and low enough so that it does not damage the substrate. Powers that may be used for in situ (direct) plasmas, powers may range from about 50 W-5 kW, e.g., 100 W-1000 W, and for remotely-generated plasmas, 0.1-10 kW, e.g., 0.1-5 kW. Various types of plasma generators may be used, including RF, microwave, etc. Frequency may vary including low frequency, e.g., 400 kHz, high frequency, e.g., 13.56 MHz, etc.

It has been found that exposing the wafer surface to a plasma including nitrogen and oxygen species enhances fill uniformity and reduces nucleation delay. It was found, unexpectedly, that such a treatment improves nucleation over exposure to oxygen-only or nitrogen-only plasmas for certain substrate materials and deposition conditions.

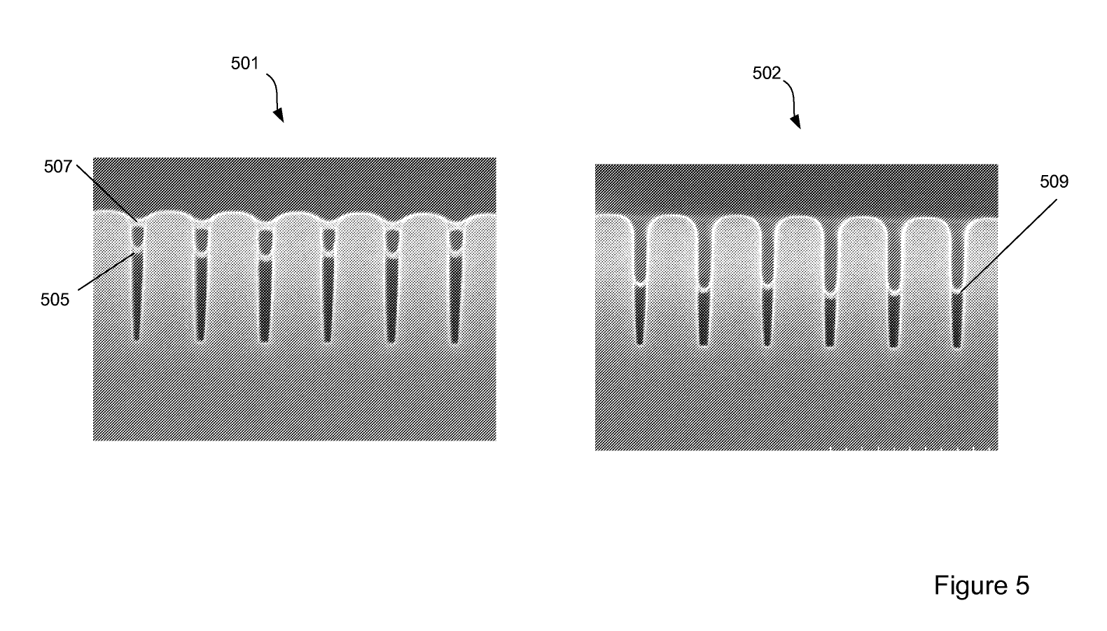

FIG. 5 shows images of gaps after two deposition cycles of undoped silicon oxide, comparing fill following a O₂/N₂ pre-treatment prior to the first deposition cycle (501) with fill without a pre-treatment (502). Each cycle include a post-deposition O₂/N₂ plasma cure. The cure results in a low density oxide with a high density crust on the top. A hydrofluoric acid etch was performed after processing and prior to imaging. The low density material etches away, leaving a void. The crust is the densified top layer. Image 501 shows two crusts 505 and 507, indicated that both deposition cycles resulted in gap fill. Image 502 shows a single crust 509, as well as less overall fill than shown in image 501. The crust 509 represents deposition during the second cycle, with the first cycle not nucleating in the absence of O2/N2 plasma pre-treatment. It is believed that the O₂/N₂ plasma cure after first cycle enabled the second cycle nucleation and deposition indicated by the presence of crust 509. In the instant example, the post-deposition plasma process conditions are the same as the pre-treatment plasma conditions, with the exception of exposure time. According to various embodiments, the post-deposition plasma conditions may be different than the pre-treatment. In one example, the pre-treatment is performed using an in situ plasma in the deposition chamber, and the post-deposition treatment is performed externally. When the substrate returns to the deposition chamber, it may undergo another in situ plasma pre-deposition treatment if needed.

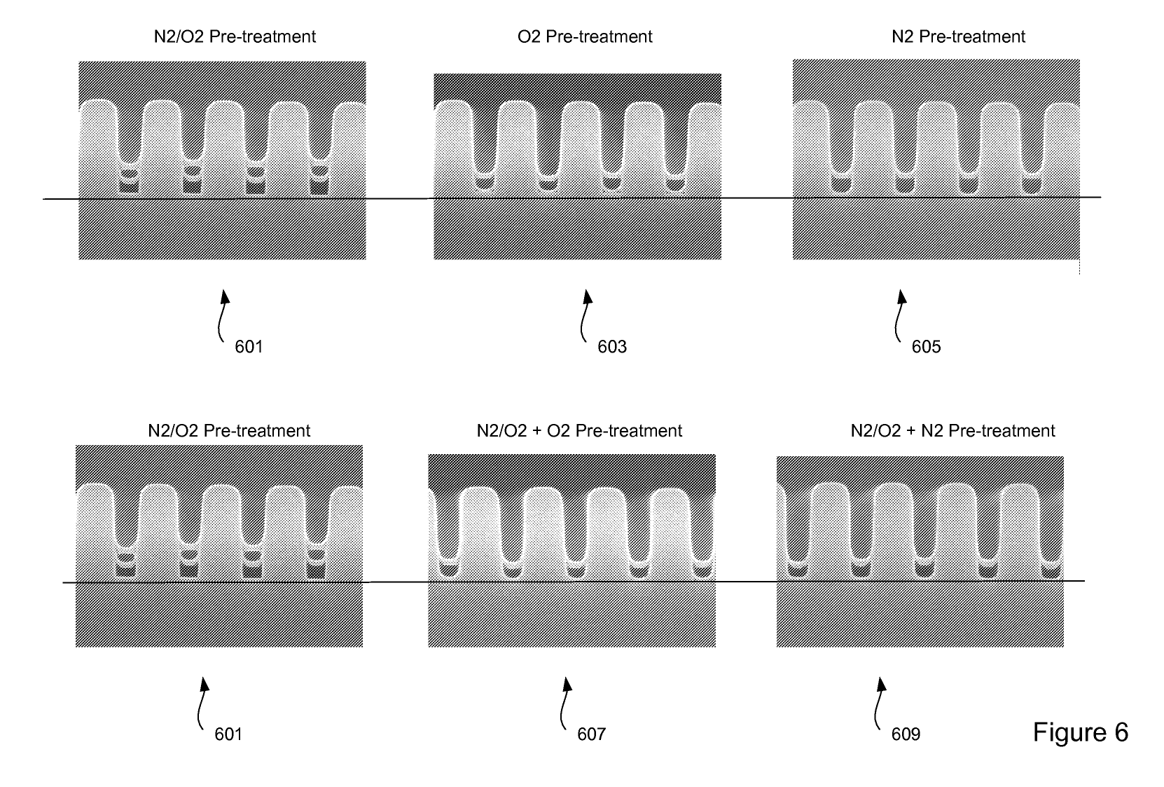

As indicated, the O₂/N₂ plasma pre-treatment was found to provide benefits not obtained by O₂ (without N₂) or N₂ (without O₂) plasmas. The images in FIG. 6 illustrate this: at 601, two-cycle gap fill after an initial O₂/N₂ pre-treatment is shown. (This image is shown in both rows to facilitate side-by-side comparisons.) At 603, two-cycle gap fill after an initial O₂ pre-treatment is shown and at 605 two-cycle gap fill after an initial N₂ pre-treatment is shown. Each cycle deposited undoped silicon oxide and included a post-deposition O₂/N₂ plasma cure. As shown by comparing the images, the O₂/N₂ pre-treatment is more effective than either the O₂ or N₂ treatment in reducing nucleation delay for the first cycle; the presence of only a single crust in the latter images indicates that substantially no deposition occurred in the first cycle after O₂ or N₂ plasma pre-treatments. A similar comparison (not depicted) for narrower features showed that a small amount of film was deposited in the first cycle after O₂ and N₂ plasma pre-treatments, but that the amount was significantly less than after O₂/N₂ pre-treatment. Images 607 and 609 show results for gaps filled after an O₂/N₂ pre-treatment was followed by an O₂ pre-treatment and a N₂ pre-treatment, respectively. The results are similar to those obtained for the O₂ and N₂ pre-treatments shown in images 603 and 605, respectively. This indicates that the O₂/N₂ pre-treatment can be made less effective by following an O₂ or N₂ plasma treatment. Without being bound by any particular theory, it is believed that the O₂/N₂ pre-treatment creates a unique surface condition that facilitates faster and more uniform nucleation of flowable oxide film. An O₂/N₂ pre-treatment also provides greater feature-to-feature fill uniformity.

The benefits of pre-treatment may be eliminated if the substrate is exposed to air or other non-inert atmosphere after the pre-treatment but before flowable oxide deposition. It has been found that at least in some case, the favorable surface termination created by the pre-treatment is not restorable by heat treatment to desorb unwanted species. Accordingly, in certain embodiments, the wafer is exposed only to vacuum or inert atmosphere between pre-treatment and deposition. In embodiments in which the pre-treatment occurs outside the deposition chamber, transfer of the pre-treated substrate to the deposition chamber is done under vacuum or inert atmosphere.

O₂:N₂ flow ratios, or more generally, O:N ratios of the pre-treatment gases flowed into the plasma generator and pre-treatment module, may range fairly broadly, from about 30:1 to about 1:10. In certain embodiments, the ratio is between about 30:1 and 1:1, or between about 25:1 and 2:1.

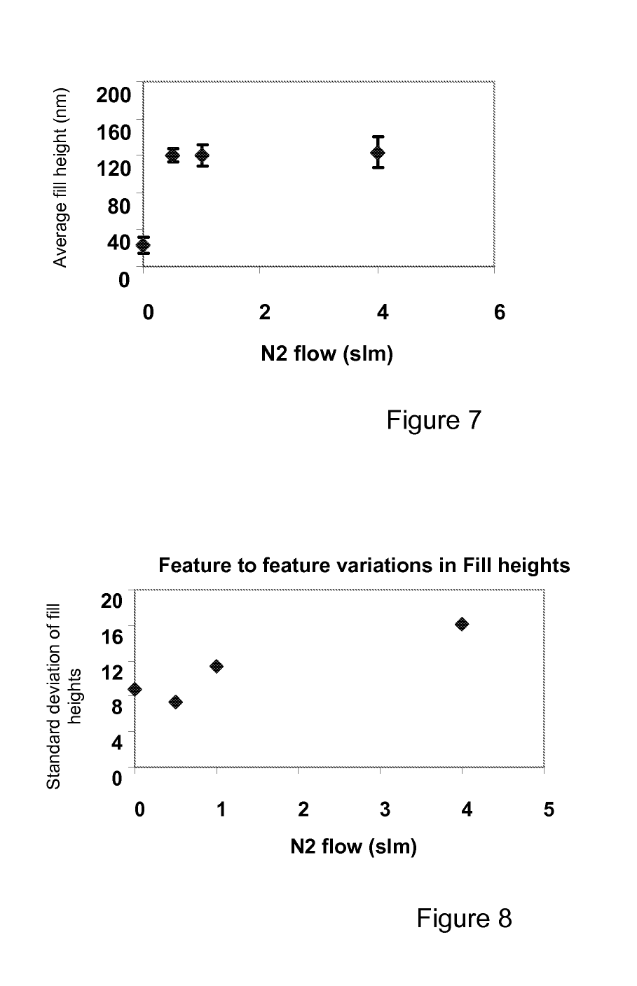

For some embodiments, fill height is relatively insensitive to N₂ flow rate, as long as some non-trace amount of nitrogen is present. This is illustrated in FIG. 7, which is a plot of undoped silicon oxide fill height for various N₂ flow rates, holding O₂ flow rate constant at 10 slm. O:N ratios of 0, 20:1, 10:1 and 2.5 (corresponding to 0, 0.5, 1 and 4 slm of N₂) are plotted. Without N₂, there is little film deposited. However, with a measurable amount of N₂ present, fill height is constant. In certain embodiments, at least about 0.1 slm or 0.25 slm of N₂ is introduced to a plasma generator. One of ordinary skill in the art will understand the flow rate may vary depending on plasma generator, if a plasma is used, the particular treatment compounds used, etc.

In certain embodiments, the O₂:N₂ flow ratio, or more generally, O:N ratio, is greater than about 2.5:1, or greater than about 10:1. This may improve feature-to-feature fill uniformity. FIG. 8 is a plot of undoped silicon oxide fill non-uniformity for various N₂ flow rates, holding O₂ flow rate constant at 10 slm. Ratios of 0, 20:1, 10:1 and 2.5 (corresponding to 0, 0.5, 1 and 4 slm of N₂) are plotted. Fill uniformity shows some dependence on N₂ flow rate, with non-uniformity increasing with N₂ flow rate.

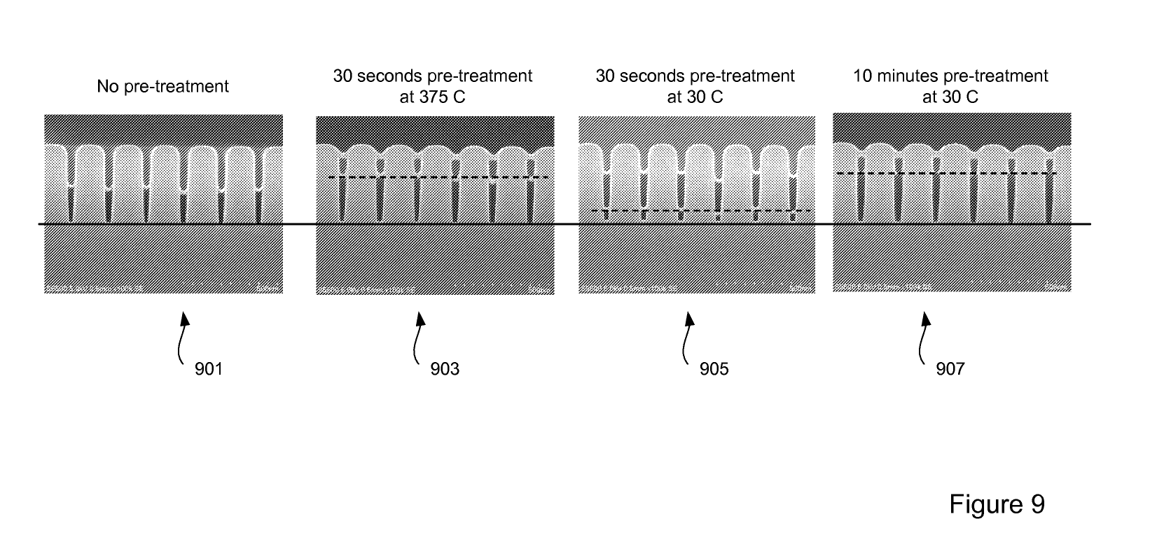

Pre-treatment exposure time may range from seconds to minutes, and may depend on the temperature, with higher temperatures resulting in more efficient pre-treatments. According to various embodiments, pre-treatment is performed at the deposition temperature or higher. In certain embodiments, the pre-treatment is performed at significantly higher temperatures than the deposition, e.g., at least about 100° C. or 200° C. higher than the deposition temperature. In certain embodiments, the pre-treatment temperature is a least about 100° C. or 200° C., or at least about 300° C., e.g., 375° C. In some embodiments, the temperature is at about 350 ° C.±25° C. FIG. 9 shows images of gaps after two depositions cycles (deposition+post-deposition O₂/N₂ cure) for various pre-treatment operations, with image 901 showing fill after no pre-treatment, 903 after O₂/N₂ plasma pre-treatment for 30 seconds at 375° C., 905 after O₂/N₂ plasma pre-treatment for 30 seconds at 30° C., and 907 after O₂/N₂ plasma pre-treatment for 10 minutes at 30° C. The dotted line indicates fill after the first deposition cycle. In certain embodiments, a pre-treatment performed in the same chamber or station as the deposition, e.g., such that the substrate is not moved in between pre-treatment and deposition, is performed at the deposition temperature.

In certain embodiments, a treatment operation involves exposing the surface to activated species generated from H₂ gas. The H₂ gas can be provided alone or with other gases. In some embodiments, the H₂ is provided without N₂ and/or O₂. A hydrogen termination can create different surface properties, potentially changing hydrophobicity, contact angle, bonding strength, adhesion and interface etch rate. A H₂ pre-treatment may be more suitable prior to deposition of certain types of films, such as carbon-doped silicon oxide films which are more hydrophobic than undoped silicon oxide films, than a N₂/O₂ pre-treatment. For example, in some cases H₂ pre-treatment prior to deposition of carbon-doped films provides good bottom up gap fill, while N₂/O₂ pre-treatment may result in incomplete coverage. Examples of gas mixtures from which H₂ activated species can be generated include H₂/He, H₂/N₂, H₂/Ar, and H₂/O₂. As described above, activated species can be formed from a gas mixture from using an in situ or remote plasma generator and/or exposure to one or more energy sources including a thermal energy source, a light source (including ultraviolet and/or infrared light sources), and microwave sources.

### Flowable Oxide Deposition

For forming silicon oxides, the process gas reactants generally include a silicon-containing compound and an oxidant, and may also include a catalyst, a solvent and other additives. The gases may also include one or more dopant precursors, e.g., a fluorine, phosphorous, carbon, nitrogen and/or boron-containing gas. Sometimes, though not necessarily, an inert carrier gas is present. In certain embodiments, the gases are introduced using a liquid injection system. In certain embodiments, the silicon-containing compound and the oxidant are introduced via separate inlets or are combined just prior to introduction into the reactor in a mixing bowl and/or showerhead. The catalyst and/or optional dopant may be incorporated into one of the reactants, pre-mixed with one of the reactants or introduced as a separate reactant. The substrate is then exposed to the process gases. Conditions in the reactor are such that the silicon-containing compound and the oxidant react to form a condensed flowable film on the substrate. Formation of the film may be aided by presence of a catalyst. The method is not limited to a particular reaction mechanism, e.g., the reaction mechanism may involve a hydrolysis reaction, polymerization reaction, condensation reaction, a vapor-phase reaction producing a vapor-phase product that condenses, condensation of one or more of the reactants prior to reaction, or a combination of these. The substrate is exposed to the process gases for a period sufficient to deposit a flowable film to fill at least some of the gap or overfill the gap as desired.

Examples of silicon containing precursors include, but are not limited to, alkoxysilanes, e.g., tetraoxymethylcyclotetrasiloxane (TOMCTS), octamethylcyclotetrasiloxane (OMCTS), tetraethoxysilane (TEOS), triethoxysilane (TES), trimethoxysilane (TriMOS), methyltriethoxyorthosilicate (MTEOS), tetramethylorthosilicate (TMOS), methyltrimethoxysilane (MTMOS), dimethyldimethoxysilane (DMDMOS), diethoxysilane (DES), dimethoxysilane (DMOS), triphenylethoxysilane, 1-(triethoxysilyl)-2-(diethoxymethylsilyl)ethane, tri-t-butoxylsilanol, hexamethoxydisilane (HMODS), hexaethoxydisilane (HEODS), tetraisocyanatesilane (TICS), bis-tert-butylamino silane (BTBAS), hydrogen silsesquioxane, tert-butoxydisilane, T8-hydridospherosiloxane, OctaHydro POSS™ (Polyhedral Oligomeric Silsesquioxane) and 1,2-dimethoxy-1,1,2,2-tetramethyldisilane. Further examples of silicon containing precursors include silane (SiH₄), disilane, trisilane, hexasilane, cyclohexasilane, and alkylsilanes, e.g., methylsilane, and ethylsilane.

In certain embodiments, the silicon-containing precursor is an alkoxysilane. Alkoxysilanes that may be used include, but are not limited to, the following:
Hₓ—Si—(OR)_{y} where x=0-3, x+y=4 and R is a substituted or unsubstituted alkyl group;
R′ₓ—Si—(OR)_{y} where x=0-3, x+y=4, R is a substituted or unsubstituted alkyl group and R′ is a substituted or unsubstituted alkyl, alkoxy or alkoxyalkane group; and
Hₓ(RO)_{y}—Si—Si—(OR)_{y}Hₓ where x=0-2, x+y=3 and R is a substituted or unsubstituted alkyl group.

In certain embodiments, carbon-doped precursors are used, either in addition to another precursor (e.g., as a dopant) or alone. Carbon-doped precursors include at least one Si—C bond. Carbon-doped precursors that may be used include, but are not limited to the, following:
R′ₓ—Si—R_{y} where x=0-3, x+y=4, R is a substituted or unsubstituted alkyl group and R′ is a substituted or unsubstituted alkyl, alkoxy or alkoxyalkane group; and
SiHₓR′_{y}—R_{z} where x=1-3, y=0-2, x+y+z=4, R is a substituted or unsubstituted alkyl group and R′ is a substituted or unsubstituted alkyl, alkoxy or alkoxyalkane group.
Examples of carbon-doped precursors are given above with further examples including, but not being limited to, trimethylsilane (3MS), tetramethylsilane (4MS), diethoxymethylsilane (DEMS), dimethyldimethoxysilane (DMDMOS), methyl-triethoxysilane (MTES), methyl-trimethoxysilane, methyl-diethoxysilane, methyl-dimethoxysilane, trimethoxymethylsilane, (TMOMS), dimethoxymethylsilane, and bis(trimethylsilyl)carbodiimide.

In certain embodiments aminosilane precursors are used. Aminosilane precursors include, but are not limited to, the following:
Hₓ—Si—(NR)_{y} where x=0-3, x+y=4 and R is an organic of hydride group.
Examples of aminosilane precursors are given above, with further examples including, but not being limited to, tris(dimethylamino)silane.

Examples of suitable oxidants include, but are not limited to ozone (O₃), peroxides including hydrogen peroxide (H₂O₂), oxygen (O₂), water (H₂O), and alcohols, such as methanol, ethanol, and isopropanol, nitric oxide (NO), nitrous dioxide (NO₂) nitrous oxide (N₂O), carbon monoxide (CO) and carbon dioxide (CO₂). In certain embodiments, a remote plasma generator may supply activated oxidant species.

One or more dopant precursors, catalysts, inhibitors, buffers, surfactants including solvents and other compounds may be introduced. Catalysts may include halogen-containing compounds, acids, or and bases. In certain embodiments, a proton donor catalyst is employed. Examples of proton donor catalysts include 1) acids including nitric, hydrofluoric, phosphoric, sulphuric, hydrochloric and bromic acids; 2) carboxylic acid derivatives including R—COOH and R—C(═O)X where R is substituted or unsubstituted alkyl, aryl, acetyl or phenol and X is a halide, as well as R—COOC—R carboxylic anhydrides; 3) SiₓX_{y}H_{z} where x=1-2, y=1-3, z=1-3 and X is a halide; 4) RₓSi—X_{y} where x=1-3 and y=1-3; R is alkyl, alkoxy, alkoxyalkane, aryl, acetyl or phenol; and X is a halide; and 5) ammonia and derivatives including ammonium hydroxide, hydrazine, hydroxylamine, and R—NH₂ where R is substituted or unsubstituted alkyl, aryl, acetyl, or phenol.

In addition to the examples given above, halogen-containing compounds which may be used include halogenated molecules, including halogenated organic molecules, such as dichlorosilane (Si₂Cl₂H₂), trichlorosilane (SiCl₃H), methylchlorosilane (SiCH₃ClH₂), chlorotriethoxysilane, chlorotrimethoxysilane, chloromethyldiethoxysilane, chloromethyldimethoxysilane, vinyltrichlorosilane, diethoxydichlorosilane, and hexachlorodisiloxane. Acids which may be used may be mineral acids such as hydrochloric acid (HCl), sulphuric acid (H₂SO₄), and phosphoric acid (H₃PO₄); organic acids such as formic acid (HCOOH), acetic acid (CH₃COOH), and trifluoroacetic acid (CF₃COOH). Bases which may be used include ammonia (NH3) or ammonium hydroxide (NH₄OH), phosphine (PH₃); and other nitrogen- or phosphorus-containing organic compounds. Additional examples of catalysts are chloro-diethoxysilane, methanesulfonic acid (CH₃ SO₃H), trifluoromethanesulfonic acid (“triflic”, CF₃SO₃H), chloro-dimethoxysilane, pyridine, acetyl chloride, chloroacetic acid (CH₂ClCO₂H), dichloroacetic acid (CHCl₂CO₂H), trichloroacetic acid (CCl₂CO₂H), oxalic acid (HO₂CCO₂H), benzoic acid (C₆H₅CO₂H), and triethylamine.

According to various embodiments, catalysts and other reactants may be introduced simultaneously or in particular sequences. For example, in some embodiments, an acidic compound may be introduced into the reactor to catalyze the hydrolysis reaction at the beginning of the deposition process, then a basic compound may be introduced near the end of the hydrolysis step to inhibit the hydrolysis reaction and the catalyze the condensation, or polymerization, reaction. Acids or bases may be introduced by rapid delivery or “puffing” to catalyze or inhibit hydrolysis or condensation reaction quickly during the deposition process. Alteration of the pH by puffing may occur at any time during the deposition process, and difference process timing and sequence may result in different films with properties desirable for different applications. Examples of other catalysts include hydrochloric acid (HCl), hydrofluoric acid (HF), acetic acid, trifluoroacetic acid, formic acid, dichlorosilane, trichlorosilane, methyltrichlorosilane, ethyltrichlorosilane, trimethoxychlorosilane, and triethoxychlorosilane. Methods of rapid delivery that may be employed are described in U.S. application Ser. No. 12/566,085, incorporated by reference herein.

Surfactants may be used to relieve surface tension and increase wetting of reactants on the substrate surface. They may also increase the miscibility of the dielectric precursor with the other reactants, especially when condensed in the liquid phase. Examples of surfactants include solvents, alcohols, ethylene glycol and polyethylene glycol. Difference surfactants may be used for carbon-doped silicon precursors because the carbon-containing moiety often makes the precursor more hydrophobic.

Solvents may be non-polar or polar and protic or aprotic. The solvent may be matched to the choice of dielectric precursor to improve the miscibility in the oxidant. Non-polar solvents include alkanes and alkenes; polar aprotic solvents include acetones and acetates; and polar protic solvents include alcohols and carboxylic compounds.

Examples of solvents that may be introduced include alcohols, e.g., isopropyl alcohol, ethanol and methanol, or other compounds, such as ethers, carbonyls, nitriles, miscible with the reactants. Solvents are optional and in certain embodiments may be introduced separately or with the oxidant or another process gas. Examples of solvents include, but not limited to, methanol, ethanol, isopropanol, acetone, diethylether, acetonitrile, dimethylformamide, and dimethyl sulfoxide. In some embodiments, the solvent may be introduced by puffing it into the reactor to promote hydrolysis, especially in cases where the precursor and the oxidant have low miscibility.

In certain embodiments, dopants are used to increase the carbon, nitrogen or silicon content of the film. For example, triethoxysilane may be doped with methyl-triethoxysilane (CH₃Si(OCH₂)₃) to introduce carbon into the as-deposited film. In an alternative implementation, the methyltriethoxysilane may be used on its own to deposit a carbon-containing film, without another precursor. Other examples of carbon-doped precursors include trimethylsilane (3MS), tetramethylsilane (4MS), diethoxymethylsilane (DEMS), dimethyldimethoxysilane (DMDMOS), methyl-trimethoxysilane (MTMS), methyl-diethoxysilane (MDES), methyl-dimethoxysilane (MDMS) and cyclic azasilanes. Additional carbon-doped precursors are described above. In certain embodiments, the film is doped with extra silicon and/or nitrogen.

In the same or other embodiments, the film may be doped during anneal, by exposing the film to a carbon-containing, nitrogen-containing and/or silicon-containing atmosphere. As described above, this may be done in the presence of an energy source, e.g., thermal, UV, plasma, or microwave energy.

In the same or other embodiments, carbon doping can involving using certain catalysts. Examples of catalysts that may be used for carbon-doped films include chloromethyldiethoxysilane, chloromethyldimethoxysilane, and vinyltrichlorosilane.

In some embodiments, a H₂ pre-treatment may be employed prior to deposition of a carbon-doped film, or other film that is more hydrophobic than undoped silicon oxide.

Sometimes, though not necessarily, an inert carrier gas is present. For example, nitrogen, helium, and/or argon, may be introduced into the chamber with one of the compounds described above.

Reaction conditions are such that the silicon-containing compound and oxidant form a flowable film. In certain embodiments, the reaction takes place in dark or non-plasma conditions. Chamber pressure may be between about 1-600 Torr, in certain embodiments, it is between 5 and 200 Torr, or 10 and 100 Torr. In a particular embodiment, chamber pressure is about 10 Torr. In other embodiments, the reaction takes place in the presence of a plasma. Methods of depositing a flowable film for gap fill via a plasma-enhanced chemical vapor deposition (PECVD) reaction are described in U.S. patent application Ser. No. 12/334,726, incorporated by reference herein.

Substrate temperature is between about −20° C. and 250° C. in certain embodiments. In certain embodiments, temperature is between about −10° C. and 80° C., or about 0° C. and 35° C. Pressure and temperature may be varied to adjust deposition time; high pressure and low temperature are generally favorable for quick deposition when utilizing absorption or condensation reactions. High temperature and low pressure will result in slower deposition time. Thus, increasing temperature may require increased pressure. In one embodiment, the temperature is about 5° C. and the pressure about 10 Torr. Exposure time depends on reaction conditions as well as the desired film thickness. Deposition rates are from about 100 angstroms/min to 1 micrometer/min according to various embodiments.

The substrate is exposed to the reactants under these conditions for a period long enough to deposit a flowable film in the gap. As indicated above, the entire desired thickness of film may be deposited in a single cycle deposition. In other embodiments which employ multiple deposition operations, only a portion of the desired film thickness is deposited in a particular cycle. In certain embodiments, the substrate is continuously exposed to the reactants, though in other embodiments, one or more of the reactants may be pulsed or otherwise intermittently introduced. Also as noted above, in certain embodiments, one or more of the reactants including a dielectric precursor, oxidant, catalyst or solvent, may be introduced prior to introduction of the remaining reactants.

In certain embodiments, the dielectric precursor, the oxidant or one of the other reactants is flowed over the pre-treated surface prior to the introduction of the other reactants.

In one example of a reaction mechanism, a silicon-containing organic precursor (e.g., a siloxane such as tri-methoxy silane or tri-ethoxy silane) and an oxidizing agent such as water are reacted. Solvents such as methanol, ethanol and isopropanol are used to improve miscibility between the silicon-containing organic precursor and water and wetting of the surface. In a hydrolyzing medium the silicon-containing precursor forms a fluid-like film on the wafer surface that preferentially deposits in trenches due to capillary condensation and surface tension forces, thus resulting in a bottom-up fill process. This fluid-like film is formed by the replacement of alkoxy groups (—OR, R being alkyl group) with —OH groups. This step in the film formation is referred to as hydrolysis. The —OH groups and the residual alkoxy groups participate in condensation reactions that lead to the release of water and alcohol molecules and the formation of Si—O—Si linkages. The as-deposited film is primarily a low density silicon oxide which may contain some unhydrolyzed Si—H bonds (originating from the silicon-containing precursor). The reaction mechanism and as-deposited film composition may vary depending on the particular reactants and reaction conditions. The flowable oxide deposition methods described herein are not limited to a particular reaction mechanism, e.g., the reaction mechanism may involve an adsorption reaction, a hydrolysis reaction, a condensation reaction, a polymerization reaction, a vapor-phase reaction producing a vapor-phase product that condenses, condensation of one or more of the reactants prior to reaction, or a combination of these. For example, in certain embodiments, peroxides are reacted with silicon-containing precursors such as alkylsilanes to form flowable films including carbon-containing silanols. One of ordinary skill in the art will understand that other known vapor deposition processes for flowable film processes may be used.

In certain embodiments, the pre-treatment operations described herein facilitate nucleation for depositions initiated by absorption and/or condensation of reactants on the wafer surface. For example, the pre-treatment operations may facilitate nucleation by a capillary condensation method as described above. Further description of such mechanisms is found in U.S. Pat. Nos. 7,074,690 and 7,524,735, incorporated by reference herein. Without being bound by a particular theory, it is believed that advantageous surface terminations are created by the pre-treatments described that enable uniform nucleation of the flowable oxide film.

### Post-Deposition Treatments

After deposition, the as-deposited film is treated according to various embodiments. According to various embodiments, one or more treatment operations are performed to do one or more of the following: introduction of a dopant, chemical conversion of the as-deposited film, and densification. In certain embodiments, a single treatment may do one or more of these.

A post-deposition treatment may be performed in situ, i.e., in the deposition chamber, or in another chamber. Densification operations, also referred to as cure or anneal operations, may be plasma-based, purely thermal, or by exposure to radiation such as ultra-violet, infra-red or microwave radiation.

Temperatures may range from 0-600° C. or even higher, with the upper end of the temperature range determined by the thermal budget at the particular processing stage. For example, in certain embodiments, an entire process carried out at temperatures less than about 400 ° C. This temperature is compatible with NiSi contacts for example. Pressures may be from 0.1-10 Torr for plasma processes with up to atmospheric pressures for other types of processes. One having ordinary skill in the art will understand that certain processes may have temperature and pressure ranges outside these ranges.

The anneal may be performed in an inert environment (Ar, He, etc.) or in a potentially reactive environment. Oxidizing environments (using O₂, N₂O, O₃, H₂O, H₂O₂, etc.) may be used, though in certain situations nitrogen-containing compounds will be avoided to prevent incorporation of nitrogen in the film. In other embodiments, nitridizing environments (using N₂, N₂O, NH₃, etc.) are used. In some embodiments, a mix of oxidizing and nitridizing environments are used.

As indicated, in certain embodiments, the film is treated by exposure to a plasma, either from a remote (or downstream) source or from an in-situ source. This may result in a top-down conversion of the flowable film to a densified solid film. The plasma may be inert or reactive. The plasma may be capacitively coupled or inductively coupled. Helium and argon plasma are examples of inert plasmas; oxygen and steam plasmas are examples of oxidizing plasmas (used for example, to remove carbon or nitrogen or to further oxidize the film as desired). Temperatures during plasma exposure are typically about 200° C. or higher. In certain embodiments, an oxygen or oxygen-containing plasma is used to remove carbon or nitrogen.

Other annealing processes, including rapid thermal processing (RTP) may also be used to solidify and/or shrink the film. If using an ex-situ process, higher temperatures and other sources of energy may be employed. Ex-situ treatments include high temperature anneals (700-1000 ° C.) in an environment such as N₂, O₂, H₂O or He. In certain embodiments, an ex situ treatment involves exposing the film to ultra-violet radiation, e.g., in a ultraviolet thermal processing (UVTP) process. For example, temperatures of 400 ° C. or above in conjunction with UV exposure may be used to cure the film. Other flash curing processes, including RTP, may be used for the ex-situ treatment as well.

In certain embodiments, a film is densified and chemically or physically converted by the same process operations. Converting a film involves using a reactive chemistry. According to various embodiments, the composition of the annealed film depends on the as-deposited film composition and the cure chemistry. For example, in certain embodiments, an Si(OH)x as-deposited film is converted to a SiO network using an oxidizing plasma cure. In other embodiments, a Si(OH)x as-deposited film is converted to a SiON network by exposure to an oxidizing and nitridizing plasma, or an SiN or an SiON as-deposited film is converted to a Si—O film.

As described above with reference to FIG. 3, in certain embodiments in which multi-cycle processes are used, exposure to a nitridizing and oxidizing plasma or other post-deposition treatment may be used to pre-treat the surface for the next deposition as well as for densification and conversion.

### Apparatus

The methods of the present invention may be performed on a wide-range of apparatuses. The deposition operations may be implemented on any chamber equipped for deposition of dielectric film, including HDP-CVD reactors, PECVD reactors, sub-atmospheric CVD reactor, any chamber equipped for CVD reactions, and chambers used for PDL (pulsed deposition layers), with the treatment operations performed using these or other chambers.

Generally, an apparatus will include one or more chambers or “reactors” (sometimes including multiple stations) that house one or more wafers and are suitable for wafer processing. Each chamber may house one or more wafers for processing. The one or more chambers maintain the wafer in a defined position or positions (with or without motion within that position, e.g. rotation, vibration, or other agitation). While in process, each wafer is held in place by a pedestal, wafer chuck and/or other wafer holding apparatus. For certain operations in which the wafer is to be heated, the apparatus may include a heater such as a heating plate.

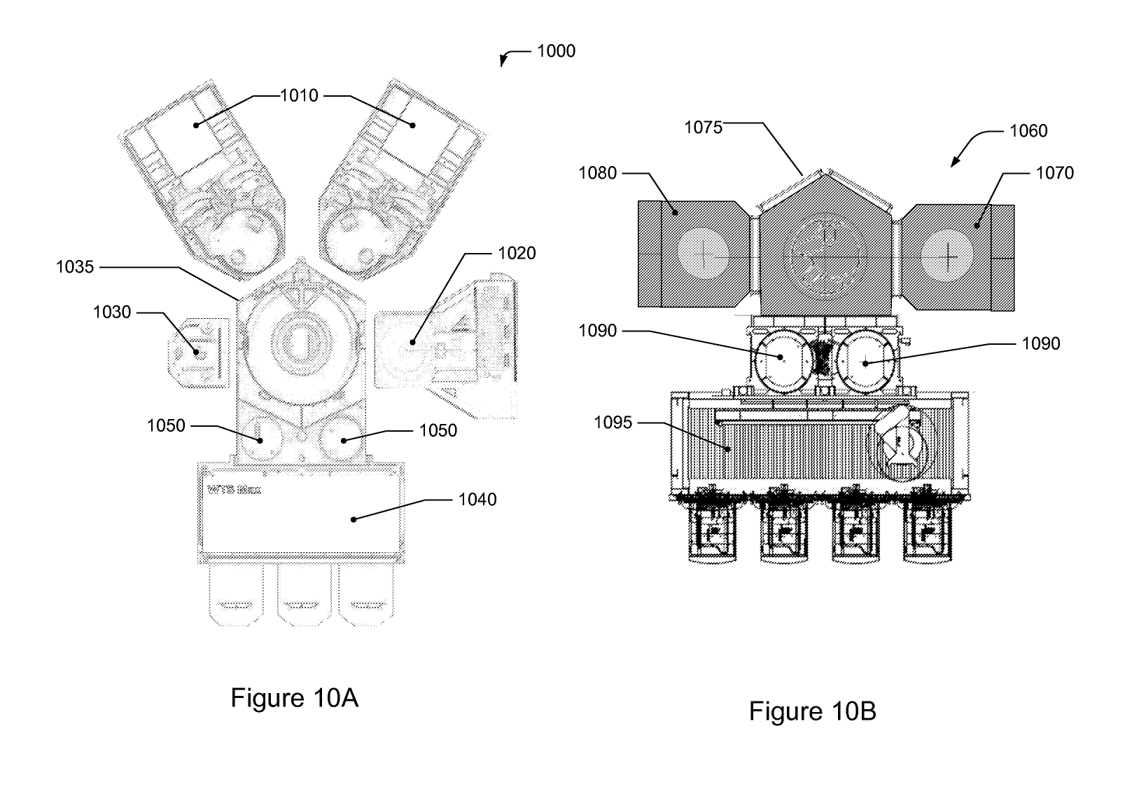

FIG. 10A depicts example tool configuration 1000 in which the tool includes two high density plasma chemical vapor deposition (HDP-CVD) modules 1010, flowable gap fill module 1020, PEC 1030, WTS (Wafer Transfer System) 1040, loadlocks 1050, in some embodiments including a wafer cooling station, and vacuum transfer module 1035. HDP-CVD modules 1010 may, for example, be Novellus SPEED MAX modules. Flowable gap fill module 1020 may, for example, be a Novellus Flowable Oxide module.

FIG. 10B provides another example tool configuration 1060 including wafer transfer system 1095 and loadlocks 1090, vacuum transfer module 1075, cure module 1070, and flowable gap fill module 1080. An additional cure module 1070 and/or flowable gap fill module 1080 may also be included. Cure module 1070 may be a plasma cure module, e.g., a remote plasma cure module, or an inductively or capacitively coupled cure module. In other embodiments, cure module 1070 is a UV cure module or a thermal cure module. In embodiments in which an in-situ anneal is performed, cure module 1070 may not be present. Examples of cure modules 1070 include Novellus SPEED or SPEED Max, Novellus Altus ExtremeFill (EFx) Module, Novellus Vector Extreme Pre-treatment Module which can be used for plasma (CLEAR module), ultra-violet (Lumier module) or infra-red treatment; or a Novellus SOLA which may be used for UV treatment.

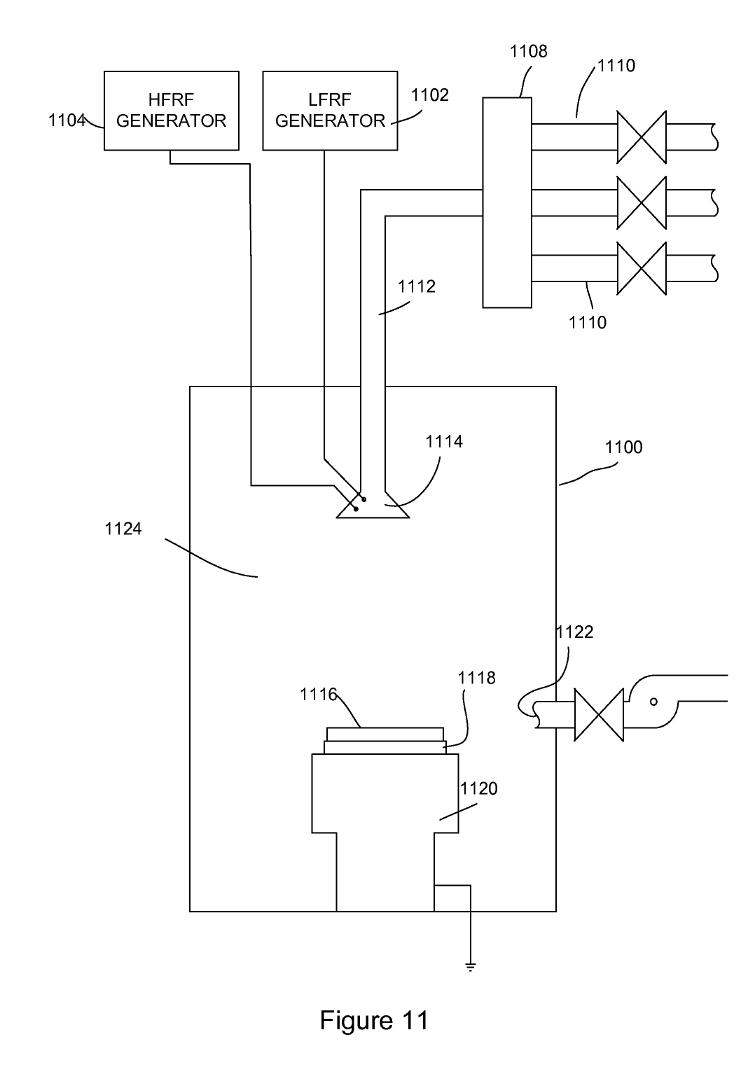

FIG. 11 shows an example of a reactor that may be used in accordance with certain embodiments of the invention, as a deposition chamber, a treatment and deposition chamber, or as an independent cure module. The reactor shown in FIG. 11 is suitable for both the dark (non-plasma) or plasma-enhanced deposition and as well as cure, for example, by capacitively-coupled plasma anneal. As shown, a reactor 1100 includes a process chamber 1124, which encloses other components of the reactor and serves to contain the plasma generated by a capacitor type system including a showerhead 1114 working in conjunction with a grounded heater block 1120. A low-frequency RF generator 1102 and a high-frequency RF generator 1104 are connected to showerhead 1114. The power and frequency are sufficient to generate a plasma from the process gas, for example 50 W-5kW total energy. In the implementation of the present invention, the generators are not used during dark deposition of the flowable film. During the plasma anneal step, one or both generators may be used. For example, in a typical process, the high frequency RF component is generally between 2-60MHz; in a preferred embodiment, the component is 13.56 MHz.

Within the reactor, a wafer pedestal 1118 supports a substrate 1116. The pedestal typically includes a chuck, a fork, or lift pins to hold and transfer the substrate during and between the deposition and/or plasma treatment reactions. The chuck may be an electrostatic chuck, a mechanical chuck or various other types of chuck as are available for use in the industry and/or research.

The process gases are introduced via inlet 1112. Multiple source gas lines 1110 are connected to manifold 1108. The gases may be premixed or not. The temperature of the mixing bowl/manifold lines should be maintained at levels above the reaction temperature. Temperatures at or above about 80 C at pressures at or less than about 20 Torr usually suffice. Appropriate valving and mass flow control mechanisms are employed to ensure that the correct gases are delivered during the deposition and plasma treatment phases of the process. In case the chemical precursor(s) is delivered in the liquid form, liquid flow control mechanisms are employed. The liquid is then vaporized and may be mixed with other process gases during its transportation in a manifold heated above its vaporization point before reaching the deposition chamber.

Process gases exit chamber 1100 via an outlet 1122. A vacuum pump 1126 (e.g., a one or two stage mechanical dry pump and/or a turbomolecular pump) typically draws process gases out and maintains a suitably low pressure within the reactor by a close loop controlled flow restriction device, such as a throttle valve or a pendulum valve.

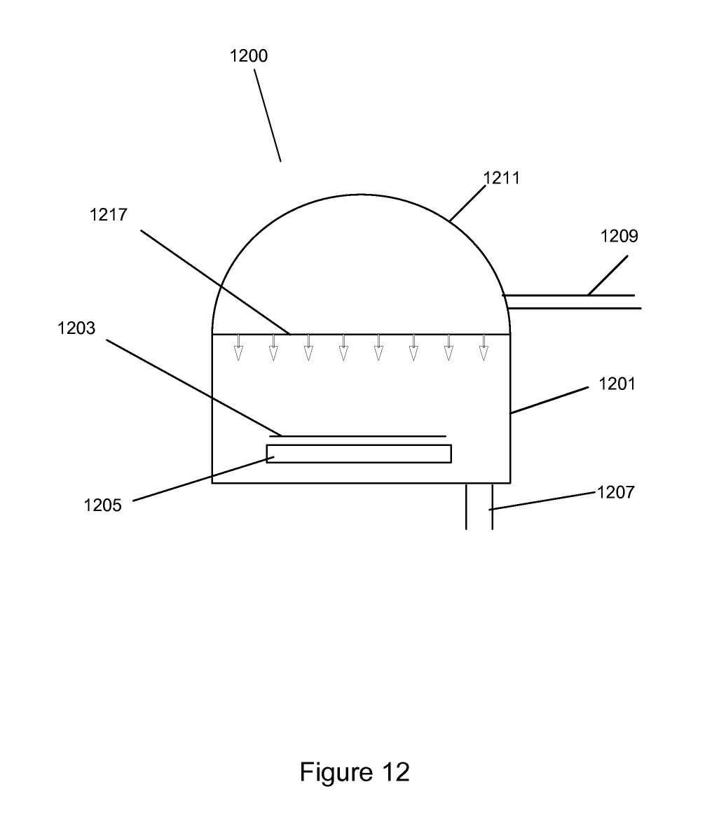

FIG. 12 illustrates a simplified schematic of a remote plasma pre-treatment and/or cure module according to certain embodiments. Apparatus 1200 has a plasma producing portion 1211 and an exposure chamber 1201 separated by a showerhead assembly or faceplate 1217. Inside exposure chamber 1201, a platen (or stage) 1205 provides a wafer support. Platen 1205 is fitted with a heating/cooling element. In some embodiments, platen 1205 is also configured for applying a bias to wafer 1203. Low pressure is attained in exposure chamber 1201 via vacuum pump via conduit 1207. Sources of gaseous treatment gases provide a flow of gas via inlet 1209 into plasma producing portion 1211 of the apparatus. Plasma producing portion 1211 may surrounded by induction coils (not shown). During operation, gas mixtures are introduced into plasma producing portion 1211, the induction coils are energized and a plasma is generated in plasma producing portion 1211. Showerhead assembly 1217 may have an applied voltage and terminates the flow of some ions and allows the flow of neutral species into exposure chamber 1201.

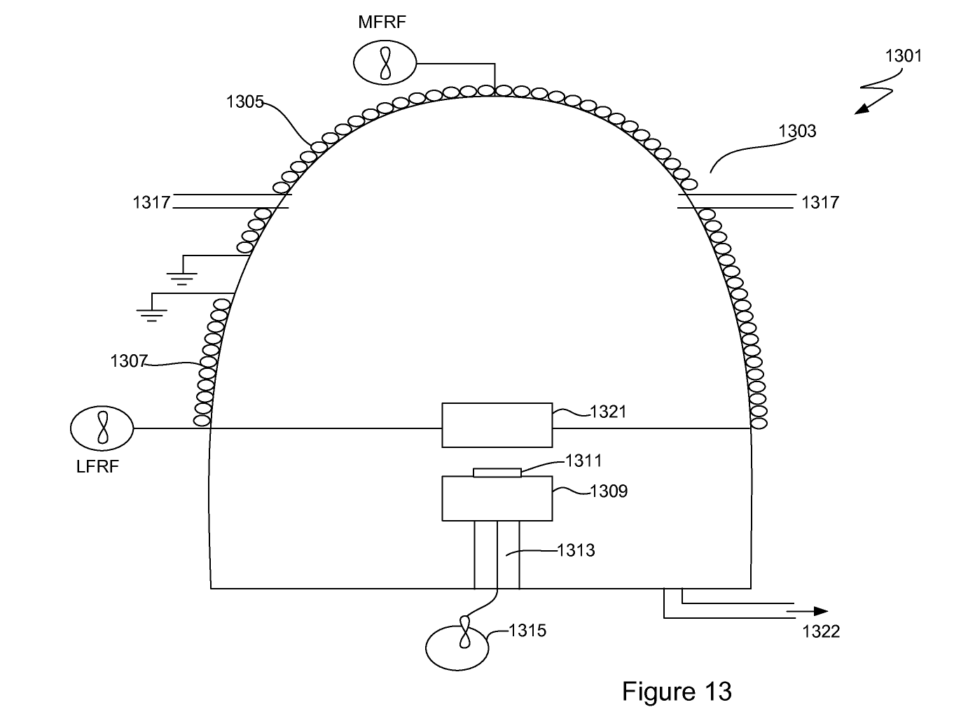

FIG. 13 is a simplified illustration of various components of a HDP-CVD apparatus that may be used for pre- and/or post-deposition treatment or cures according to various embodiments. As shown, a reactor 1301 includes a process chamber 1303 which encloses other components of the reactor and serves to contain the plasma. In one example, the process chamber walls are made from aluminum, aluminum oxide, and/or other suitable material. The embodiment shown in FIG. 13 has two plasma sources: top RF coil 1305 and side RF coil 1307. Top RF coil 1305 is a medium frequency or MFRF coil and side RF coil 1307 is a low frequency or LFRF coil. In the embodiment shown in FIG. 13, MFRF frequency may be from 430-470 kHz and LFRF frequency from 340-370 kHz. However, apparatuses having single sources and/or non-RF plasma sources may be used.

Within the reactor, a wafer pedestal 1309 supports a substrate 1311. A heat transfer subsystem including a line 1313 for supplying heat transfer fluid controls the temperature of substrate 1311. The wafer chuck and heat transfer fluid system can facilitate maintaining the appropriate wafer temperatures.

A high frequency RF of HFRF source 1315 serves to electrically bias substrate 1311 and draw charged precursor species onto the substrate for the pre-treatment or cure operation. Electrical energy from source 1315 is coupled to substrate 1311 via an electrode or capacitive coupling, for example. Note that the bias applied to the substrate need not be an RF bias. Other frequencies and DC bias may be used as well.

The process gases are introduced via one or more inlets 1317. The gases may be premixed or not. The gas or gas mixtures may be introduced from a primary gas ring 1321, which may or may not direct the gases toward the substrate surface. Injectors may be connected to the primary gas ring 1321 to direct at least some of the gases or gas mixtures into the chamber and toward substrate. The injectors, gas rings or other mechanisms for directing process gas toward the wafer are not present in certain embodiments. Process gases exit chamber 1303 via an outlet 1322. A vacuum pump typically draws process gases out and maintains a suitably low pressure within the reactor. While the HDP chamber is described in the context of pre- and/or post-deposition treatment or cure, in certain embodiments, it may be used as a deposition reactor for deposition of a flowable film. For example, in a thermal (non-plasma) deposition, such a chamber may be used without striking a plasma.

FIGS. 11-13 provide examples of apparatuses that may be used to implement the pre-treatments described herein. However, one of ordinary skill in the art will understand that various modifications may be made from the description. For example, one or more UV light sources or other energy sources may be disposed relative to the treatment chamber and/or gas inlet such that a treatment gas can be exposed to radiation from the one or more UV light sources (or energy from the other energy source(s)). According to various embodiments, one or more UV light sources may be within or outside the treatment chamber. If outside, a UV-transparent window may allow UV radiation to enter the treatment chamber. In some embodiments, a UV light source may be positioned to irradiate a treatment gas prior to the gas being inlet to the chamber. Further description of apparatuses that may be used to implement the methods described herein are provided in U.S. Provisional Patent Application No. 61/425,150, incorporated by reference herein.

In certain embodiments, a system controller is employed to control process parameters. The system controller typically includes one or more memory devices and one or more processors. The processor may include a CPU or computer, analog and/or digital input/output connections, stepper motor controller boards, etc. Typically there will be a user interface associated with system controller. The user interface may include a display screen, graphical software displays of the apparatus and/or process conditions, and user input devices such as pointing devices, keyboards, touch screens, microphones, etc. The system controller may be connected to any or all of the components shown in FIGS. 10A or 10B of a tool; its placement and connectivity may vary based on the particular implementation.

In certain embodiments, the system controller controls the pressure in the processing chambers. The system controller may also control concentration of various process gases in the chamber by regulating valves, liquid delivery controllers and MFCs in the delivery system as well as flow restriction valves to an exhaust line. The system controller executes system control software including sets of instructions for controlling the timing, flow rates of gases and liquids, chamber pressure, substrate temperature, and other parameters of a particular process. Other computer programs stored on memory devices associated with the controller may be employed in some embodiments. In certain embodiments, the system controller controls the transfer of a substrate into and out of various components of the apparatuses shown in FIGS. 10A and 10B.

The computer program code for controlling the processes in a process sequence can be written in any conventional computer readable programming language: for example, assembly language, C, C++, Pascal, Fortran or others. Compiled object code or script is executed by the processor to perform the tasks identified in the program. The system software may be designed or configured in many different ways. For example, various chamber component subroutines or control objects may be written to control operation of the chamber components necessary to carry out the described processes. Examples of programs or sections of programs for this purpose include process gas control code, pressure control code, and plasma control code.

The controller parameters relate to process conditions such as, for example, timing of each operation, pressure inside the chamber, substrate temperature, chamber temperature, gas delivery temperatures, process gas flow rates, RF power, as well as others described above. These parameters are provided to the user in the form of a recipe, and may be entered utilizing the user interface. Signals for monitoring the process may be provided by analog and/or digital input connections of the system controller. The signals for controlling the process are output on the analog and digital output connections of the apparatus.

The disclosed methods and apparatuses may also be implemented in systems including lithography and/or patterning hardware for semiconductor fabrication. Further, the disclosed methods may be implemented in a process with lithography and/or patterning processes preceding or following the disclosed methods. The apparatus/process described hereinabove may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically comprises some or all of the following steps, each step enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

Although the foregoing invention has been described in some detail for purposes of clarity of understanding, it will be apparent that certain changes and modifications may be practiced within the scope of the appended claims. It should be noted that there are many alternative ways of implementing the processes, systems and apparatus of the present invention. Accordingly, the present embodiments are to be considered as illustrative and not restrictive, and the invention is not to be limited to the details given herein.

1. A method comprising:
providing a substrate including a gap to be filled to a treatment chamber, the gap including a bottom surface and one or more sidewall surfaces;
exposing a surface of the gap to nitrogen and oxygen species; and
after exposing the surface of the gap to nitrogen and oxygen species, depositing a flowable dielectric film in the gap.

2. The method of claim 1 wherein depositing a flowable dielectric film in the gap comprises introducing a silicon-containing precursor and an oxidant in a chamber containing the substrate under conditions such that the flowable dielectric film is formed.

3. The method of claim 1 further comprising:
densifying at least a portion of the deposited film.

4. The method of claim 1 wherein the surface is a solid silicon-containing material.

5. The method of claim 1 wherein the gap surface is exposed to nitrogen and oxygen species prior to the deposition of any flowable dielectric film in the gap.

6. (canceled)

7. The method of claim 1 further comprising generating a plasma from a gas comprising a nitrogen-containing compound and an oxygen-containing compound.

8. (canceled)

9. The method of claim 7 wherein the plasma is a remotely-generated plasma.

10. The method of claim 7 wherein the plasma is generated in the treatment chamber.

11. The method of claim 1 wherein the nitrogen and oxygen species comprise ions and/or radicals.

12. The method of claim 1 wherein exposing the gap to nitrogen and oxygen species comprises introducing nitrogen and oxygen to the treatment chamber in a ratio of between about 1:2 to 1:30.

13. The method of claim 1 wherein exposing the gap to nitrogen and oxygen species comprises introducing nitrogen and oxygen to the treatment chamber in a ratio of between about 1:5 to 1:30.

14. The method of claim 1 wherein exposing the gap to nitrogen and oxygen species comprises introducing nitrogen and oxygen to the treatment chamber in a ratio of between about 1:10 to 1:20.

15. The method of claim 1 further comprising exposing the deposited film to a plasma generated from a gas comprising a nitrogen-containing compound and an oxygen-containing compound.

16. The method of claim 1 wherein the flowable dielectric material is deposited in the treatment chamber.

17. The method of claim 1 further comprising, after exposing the surface to nitrogen and oxygen species and prior to depositing the flowable dielectric film, transferring the substrate to a deposition chamber.

18. The method of claim 1 further comprising generating nitrogen plasma species from one more of the following gases: N₂, NH₃, N₂H₄, N₂O, NO and NO_{2;} and generating oxygen species from one or more of the following gases: O₂, O₃, H₂O, H₂O₂, NO, NO₂ and CO₂.

19. The method of claim 1 further comprising, prior to depositing a flowable film in the gap, flowing a silicon-containing precursor into the chamber.

20. The method of claim 1 further comprising, prior to depositing a flowable film in the gap, flowing an oxidant into the chamber.

21. The method of claim 1 wherein exposing a surface of the gap to nitrogen and oxygen species and depositing a flowable dielectric film in the gap are performed in the same chamber.

22. The method of claim 1 further comprising exposing a surface of the gap to ultraviolet light in the presence of oxygen and nitrogen species.

23-26. (canceled)

27. A method comprising:
providing a substrate including a gap to be filled to a treatment chamber, the gap including a bottom surface and one or more sidewall surfaces;
exposing a surface of the gap to activated species generated from a gas comprising at least one of an oxygen-containing gas, a hydrogen-containing gas, and a nitrogen-containing gas; and
after exposing the surface of the gap to the activated species, depositing a flowable dielectric film in the gap.

28. The method of claim 27, wherein the gas includes hydrogen (H₂) and substantially no oxygen- or nitrogen-containing compounds.

29. The method of claim 28, wherein the flowable dielectric film is a carbon-doped dielectric film.

30. The method of claim 27, wherein the gas includes an oxygen-containing compound and substantially no nitrogen-containing compounds.

31. The method of claim 27, wherein the gas includes a nitrogen-containing compound and substantially no oxygen-containing compounds.

32. The method of claim 27, wherein the gas is selected from one of H₂, H₂/N₂, H₂/O₂, O₂, O3, N₂, NH3 and N₂/O₂, each of which may optionally include one or more inert gases.

33. A method comprising:
providing a substrate including a gap to be filled to a treatment chamber, the gap including a bottom surface and one or more sidewall surfaces;
exposing a gas comprising at least one of an oxygen-containing gas, a hydrogen-containing gas, and a nitrogen-containing gas to ultraviolet light to generate activated species;
exposing a surface of the gap to the activated species; and
after exposing the surface of the gap to the activated species, depositing a flowable dielectric film in the gap.

34. An apparatus comprising:
a treatment chamber configured to contain a partially manufactured semiconductor substrate;
a deposition chamber configured to contain a partially manufactured semiconductor substrate; and
a controller comprising program instructions for:
introducing activated species to the treatment chamber while it contains the substrate;
transferring the substrate under vacuum to the deposition chamber; and
introducing a silicon-containing precursor and an oxidant to the deposition chamber to thereby deposit a flowable oxide film on the substrate.

35-36. (canceled)
